(19) United States
(12) Patent Application Publication
(10) Pub. No.: US 2024/0037300 A1
(43) Pub. Date: Feb. 1, 2024

(54) MODELLING A CONDENSATE BLOCKAGE EFFECT IN A SIMULATION MODEL

(71) Applicant: SAUDI ARABIAN OIL COMPANY, Dhahran (SA)

(72) Inventors: Jubril Oluwa, Dhahran (SA); Ali Essa Al-Mahfoudh, Qatif (SA)

(73) Assignee: SAUDI ARABIAN OIL COMPANY, Dhahran (SA)

(21) Appl. No.: 17/877,787

(22) Filed: Jul. 29, 2022

(51) Int. Cl. G06F 30/28; E21B 49/08

(52) U.S. Cl. CPC G06F 30/28; E21B 49/087; G06F 2113/08

(57) ABSTRACT

A coarse grid model with a plurality of grid cells in a plurality of layers is provided. Model data are provided for a reservoir region of interest, and a plurality of pressure values are determined for the grid cells corresponding to a wellbore and for those not corresponding to the wellbore. A flowrate is determined at the grid cells corresponding to the wellbore based on the pressure values and on a flowrate metric. The flowrate metric is a function of well index, a pressure quantity, and a mobility variable, where the mobility variable is a non-linear function of gas condensate saturation and pressure. Also determined is a subset of the grid cells not corresponding to the wellbore where a pressure value is less than dew pressure. A flowrate for the subset of the one or more grid cells is determined based on the pressure values and on the flowrate metric.

### BACKGROUND

In gas condensate wells, condensate blockage is understood as a reduction in gas

mobility near or at a distance from the wellbore. Generally, the condensate blockage phenomenon is typically exhibited when the well pressure falls to less than a dew point pressure for a given composition, that is, a pressure value where a liquid phase condenses from a gas phase of the given composition.

### SUMMARY

This Summary is provided to introduce a selection of concepts that are further described in the Detailed Description. This Summary is not intended to identify key or essential features of the claimed subject matter, nor is it intended to be used as an aid in limiting the scope of the claimed subject matter.

In one aspect, embodiments disclosed herein relate to a method including: providing, by a computer processor, a coarse grid model comprising a plurality of grid cells in a plurality of layers, including grid cells corresponding to a wellbore and grid cells not corresponding to the wellbore; providing, using the computer processor, model data for a reservoir region of interest; determining, using the computer processor, a plurality of pressure values for the grid cells corresponding to the wellbore and for the grid cells not corresponding to the wellbore, based on the model data for the reservoir region of interest; and determining, using the computer processor, a flowrate at the grid cells corresponding to the wellbore based on the determined pressure values and on a predetermined flowrate metric. The flowrate metric is a function of well index, a pressure quantity, and a mobility variable, and the mobility variable is a non-linear function of gas condensate saturation and pressure. The method further includes: determining, using the computer processor, a subset of the grid cells not corresponding to the wellbore where a determined pressure value is less than dew pressure; and determining, using the computer processor, a flowrate for the determined subset of the one or more grid cells based on the determined pressure values and on the predetermined flowrate metric.

In one aspect, embodiments disclosed herein relate to a system including a reservoir simulator comprising a computer processor. The reservoir simulator includes functionality for: providing a coarse grid model comprising a plurality of grid cells in a plurality of layers, including grid cells corresponding to a wellbore and grid cells not corresponding to the wellbore; providing model data for a reservoir region of interest; determining a plurality of pressure values for the grid cells corresponding to the wellbore and for the grid cells not corresponding to the wellbore, based on the model data for the reservoir region of interest; and determining a flowrate at the grid cells corresponding to the wellbore based on the determined pressure values and on a predetermined flowrate metric. The flowrate metric is a function of well index, a pressure quantity, and a mobility variable, and the mobility variable is a non-linear function of gas condensate saturation and pressure. The reservoir simulator further includes functionality for: determining a subset of the grid cells not corresponding to the wellbore where a determined pressure value is less than dew pressure; and determining a flowrate for the determined subset of the one or more grid cells based on the determined pressure values and on the predetermined flowrate metric.

In one aspect, embodiments disclosed herein relate to a non-transitory computer

readable medium storing instructions executable by a computer processor, the instructions comprising functionality for: providing a coarse grid model comprising a plurality of grid cells in a plurality of layers, including grid cells corresponding to a wellbore and grid cells not corresponding to the wellbore; providing model data for a reservoir region of interest; determining a plurality of pressure values for the grid cells corresponding to the wellbore and for the grid cells not corresponding to the wellbore, based on the model data for the reservoir region of interest; and determining a flowrate at the grid cells corresponding to the wellbore based on the determined pressure values and on a predetermined flowrate metric. The flowrate metric is a function of well index, a pressure quantity, and a mobility variable, and the mobility variable is a non-linear function of gas condensate saturation and pressure. The instructions further include functionality for: determining a subset of the grid cells not corresponding to the wellbore where a determined pressure value is less than dew pressure; and determining a flowrate for the determined subset of the one or more grid cells based on the determined pressure values and on the predetermined flowrate metric.

Other aspects and advantages of the claimed subject matter will be apparent from

the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1 schematically illustrates a wellbore and related components in accordance with one or more embodiments.

FIG. 2A schematically illustrates a geological region in accordance with one or more embodiments.

FIG. 2B schematically illustrates a reservoir grid model in accordance with one or more embodiments.

FIG. 3 schematically illustrates one layer of a conventional coarse grid model for a condensate rich gas reservoir, where a pseudo-pressure function is applied solely to a wellbore location.

FIG. 4 schematically illustrates one layer of a coarse grid model for a condensate rich gas reservoir, where a pseudo-pressure function is additionally applied away from the wellbore location.

FIG. 5 shows a flowchart of a method in accordance with one or more embodiments.

FIG. 6 schematically illustrates a computing device and related components, in accordance with one or more embodiments.

### DETAILED DESCRIPTION

In the following Detailed Description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (for example, first, second, third,) may be used as an adjective for an element (that is, any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Turning now to the figures, it should be noted that the flowchart and block diagrams therein illustrate the architecture, functionality, and operation of possible implementations of systems, apparatuses, methods, and computer program products according to one or more embodiments. In this regard, each block in the flowchart or block diagrams may represent a segment, module, or portion of code, which comprises at least one executable instruction for implementing the specified logical function(s). It should also be noted that, in some alternative implementations, the functions noted in the block may occur out of the order noted in the figures. For example, two blocks shown in succession may be executed substantially concurrently, or the blocks may sometimes be executed in the reverse order, depending upon the functionality involved. Additionally, any block shown in a flowchart or block diagram may in instances be regarded as individually dispensable or interchangeable, thus not necessarily dependent on being included with one or more other blocks shown in the same diagram. It will also be noted that each block of the block diagrams or flowchart illustrations, and combinations of blocks in the block diagrams or flowchart illustrations, can be implemented by special purpose hardware-based systems that perform the specified functions or acts, or combinations of special purpose hardware and computer instructions.

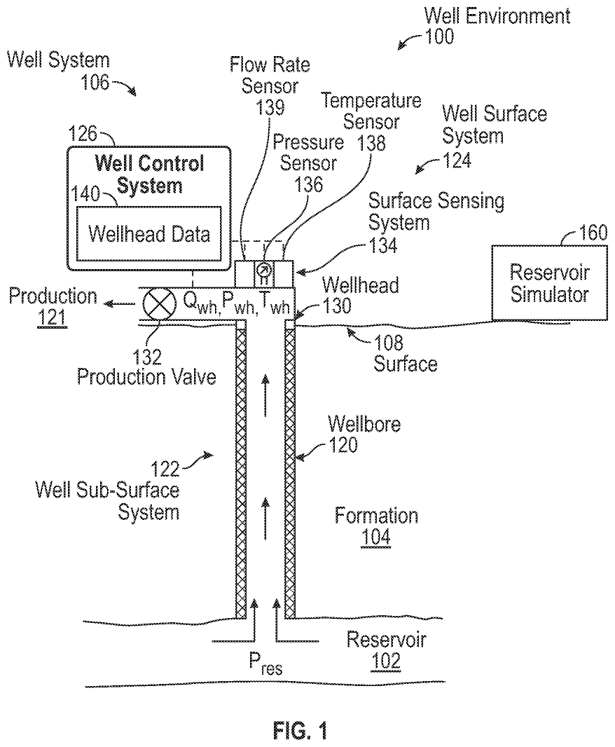

To facilitate easier reference when describing FIGS. 1 through 6, reference numerals may be advanced by a multiple of 100 in indicating a similar or analogous component or element among FIGS. 1-6.

The modelling of condensate blockage effects in gas reservoirs is known, but the complexity inherent in modelling such condensate rich gas reservoirs presents unique challenges.

In general, embodiments of the disclosure include systems and methods for simulating a hydrocarbon-bearing reservoir, particularly a gas condensate reservoir. For example, a gas condensate reservoir may have hydrocarbon deposits that are primarily a gas-phase hydrocarbon (that is, “natural-gas”) at an initial reservoir pressure. When natural-gas production begins from a production well, the reservoir pressure decreases more rapidly near the wellbore than at distances away from the wellbore. The reduced pressure around a wellbore may cause liquid phase hydrocarbons to condense from the natural-gas (that is, gas condensates; for the purpose of this application gas condensate and hydrocarbon liquids, such as crude oil, are referred to collectively as “oil”) and accumulate in a region around the wellbore called the “oil condensation zone”. As oil may be less mobile than gas, oil may have greater difficulty flowing through rock pores. Furthermore, a build-up of condensed oil in a region near a wellbore may also block paths for gas through the rock pores.

As such, by way of general background in accordance with one or more embodiments, FIG. 1 schematically illustrates a wellbore and related components. As shown in FIG. 1, a well environment 100 includes a hydrocarbon reservoir (“reservoir”) 102 located among subsurface formations (“formations”) 104 and a well system 106. The formations 104 may include a porous or fractured rock formations that resides underground beneath the earth's surface (“surface”) 108. In the case of the well system 106 being a hydrocarbon production well, the reservoir 102 may include a portion of the formations 104. The formations 104 and the reservoir 102 may include different layers of rock having varying characteristics, such as permeability, porosity, and resistivity. In the case of the well system 106 being operated as a production well, the well system 106 may facilitate the extraction of hydrocarbons (or “production”) from the reservoir 102.

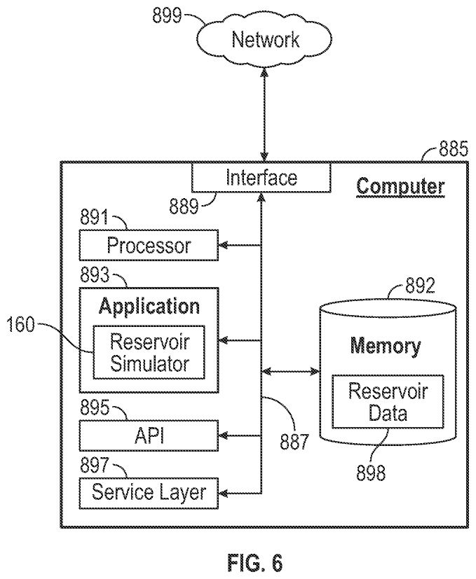

The well system 106 includes a wellbore 120, a well sub-surface system 122, a well surface system 124, and a well control system (“control system”) 126. The control system 126 may control various operations of the well system 106, such as well production operations, well completion operations, well maintenance operations, and reservoir monitoring, assessment and development operations. The control system 126 includes a computer that may be the same as or similar to that of computer 885 described in FIG. 6 and the accompanying forthcoming description.

The wellbore 120 may include a bored hole that extends from the surface 108 into a target zone of the formations 104, such as the reservoir 102. An upper end of the wellbore 120, terminating at or near the surface 108, may be referred to as the “uphole” end of the wellbore 120, and a lower end of the wellbore, terminating in the formations 104, may be referred to as the “downhole” end of the wellbore 120. The wellbore 120 may facilitate the circulation of drilling fluids during drilling operations, the flow of hydrocarbon production (“production”) 121 (for example, oil and gas) from the reservoir 102 to the surface 108 during production operations, the injection of substances (for example, water) into the formations 104 or the reservoir 102 during injection operations, or the communication of monitoring devices (for example, logging tools) into the formations 104 or the reservoir 102 during monitoring operations (for example, during in situ logging operations).

In accordance with one or more embodiments, during operation of the well system 106, the control system 126 collects and records wellhead data 140 for the well system 106. The wellhead data 140 may include, for example, a record of measurements of wellhead pressure (P_{wh}) (for example, including flowing wellhead pressure), wellhead temperature (T_{wh}) (for example, including flowing wellhead temperature), wellhead production rate (Q_{wh}) over some or all of the life of the well 106, and water cut data. In some embodiments, the measurements are recorded in real-time and are available for review or use within seconds, minutes, or hours of the condition being detected (for example, the measurements are available within 1 hour of the condition being sensed). In such an embodiment, the wellhead data 140 may be referred to as “real-time” wellhead data 140. Real-time wellhead data 140 may enable an operator of the well 106 to assess a relatively current state of the well system 106, and make real-time decisions regarding development of the well system 106 and the reservoir 102, such as on-demand adjustments in regulation of production flow from the well.

In accordance with one or more embodiments, the well surface system 124 includes a wellhead 130. The wellhead 130 may include a rigid structure installed at the “up-hole” end of the wellbore 120 at or near where the wellbore 120 terminates at the Earth's surface 108. The wellhead 130 may include structures for supporting (or “hanging”) casing and production tubing extending into the wellbore 120. Production 121 may flow through the wellhead 130 after exiting the wellbore 120 and the well sub-surface system 122, including the casing and the production tubing. In some embodiments, the well surface system 124 includes flow regulating devices that are configured to control the flow of substances into and out of the wellbore 120. For example, the well surface system 124 may include one or more production valves 132 that are operable to control the flow of production 121. For example, a production valve 132 may be fully opened to enable unrestricted flow of production 121 from the wellbore 120, the production valve 132 may be partially opened to partially restrict (or “throttle”) the flow of production 121 from the wellbore 120, and production valve 132 may be fully closed to fully restrict (or “block”) the flow of production 121 from the wellbore 120, and through the well surface system 124.

In accordance with one or more embodiments, the well surface system 124 may include a surface sensing system 134. The surface sensing system 134 may include sensors for sensing characteristics of substances, including production 121 passing through or otherwise located in the well surface system 124. The characteristics may include pressure, temperature, and flow rate of production 121 flowing through the wellhead 130, or other conduits of the well surface system 124 after exiting the wellbore 120.

In accordance with one or more embodiments, the surface sensing system 134 may include a surface pressure sensor 136 configured to sense the pressure of production 121 flowing through the well surface system 124 after production 121 exits the wellbore 120. The surface pressure sensor 136 may include a wellhead pressure sensor that senses a pressure of production 121 flowing through or otherwise located in the wellhead 130. In some embodiments, the surface sensing system 134 may include a surface temperature sensor 138 configured to sense the temperature of production 121 flowing through the well surface system 124 after it exits the wellbore 120. The surface temperature sensor 138 may include a wellhead temperature sensor that senses a temperature of production 121 flowing through or otherwise located in the wellhead 130, referred to as “wellhead temperature” (T_{wh}). In some embodiments, the surface sensing system 134 includes a flow rate sensor 139 configured to sense the flow rate of production 121 flowing through the well surface system 124 after it exits the wellbore 120. The flow rate sensor 139 may include hardware that senses a flow rate of production 121 (Q_{wh}) passing through the wellhead 130.

In accordance with one or more embodiments, the well system 106 includes a reservoir simulator 160. For example, the reservoir simulator 160 may include hardware or software with functionality for generating one or more reservoir models regarding the formations 104 or performing one or more reservoir simulations. For example, the reservoir simulator 160 may store model data for a reservoir region of interest (that is, a reservoir region for which a modelling of flowrates is desired), including well logs and data regarding core samples for performing simulations. Model data may also include a plurality of rock properties, a plurality of fluid properties, and a plurality of relative permeability values within the reservoir region of interest. A reservoir simulator may further analyze the well log data, the core sample data, seismic data, and other types of data to generate and update the one or more reservoir models. While the reservoir simulator 160 is shown at a well site, embodiments are contemplated where reservoir simulators are located away from well sites. As such, the reservoir simulator 160 may constitute a portion of a computer system that is the same as or in communication with the computer system 885 described forthcoming with regard to FIG. 6.

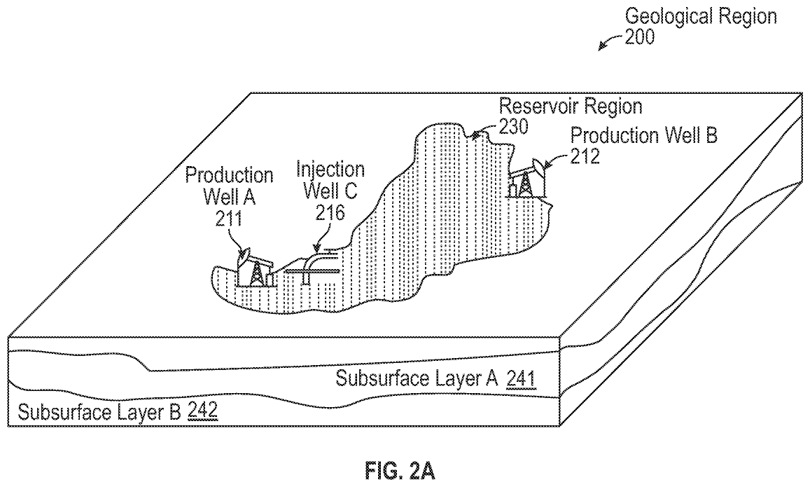

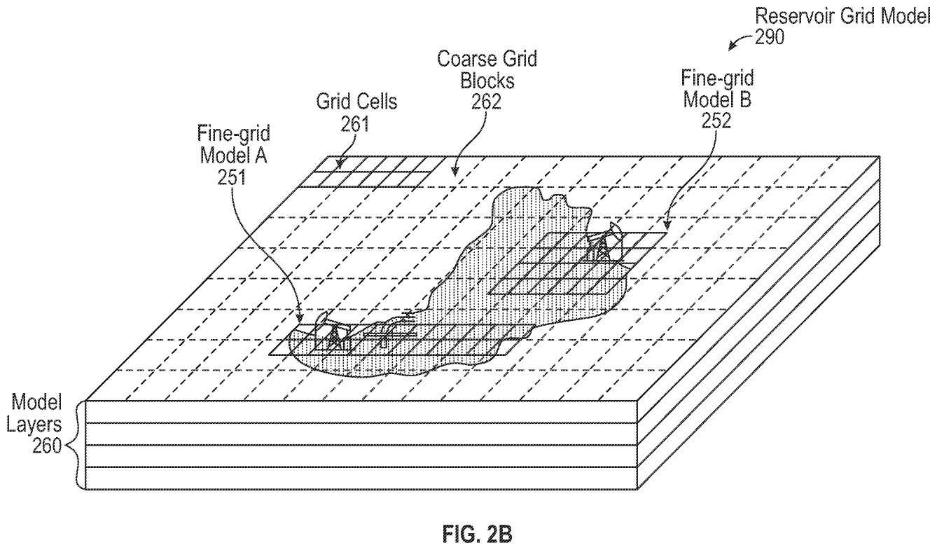

FIG. 2A schematically illustrates a geological region in accordance with one or more embodiments. As illustrated, geological region 200 may include one or more reservoir regions (for example, reservoir region 230) with various production wells (for example, production well A 211, production well B 212). For example, a production well may be similar to the well system 106 described above in FIG. 1 and the accompanying description. Likewise, a reservoir region may also include one or more injection wells (for example, injection well C 216) that include functionality for enhancing production by one or more neighboring production wells. As shown in FIG. 2A, wells may be disposed in the reservoir region 230 above various subsurface layers (for example, subsurface layer A 241, subsurface layer B 242), which may include hydrocarbon deposits. In particular, production data and/or injection data may exist for a particular well, where production data may include data that describes production or production operations at a well, such as wellhead data 140 described in FIG. 1 and the accompanying description.

FIG. 2B schematically illustrates a reservoir grid model in accordance with one or more embodiments. As illustrated in FIG. 2B, reservoir grid model 290 corresponds to the geological region 200 from FIG. 2A. More specifically, the reservoir grid model 290 includes grid cells 261 that may refer to an original cell of a reservoir grid model as well as coarse grid blocks 262 that may refer to an amalgamation of original cells of the reservoir grid model. For example, a grid cell may be the case of a 1×1 block, where coarse grid blocks may be of various sizes, such as 2×2, 4×4, and 8×8 blocks. Both the grid cells 261 and the coarse grid blocks 262 may correspond to columns for multiple model layers 260 within the reservoir grid model 290. Thus, in this connection, a plurality of grid cells 261 (in different layers) may correspond to a wellbore within the grid model.

Conventionally, prior to performing a reservoir simulation, local grid refinement and coarsening (LGR) may be used to increase or decrease grid resolution in a certain area of reservoir grid model. For example, various reservoir properties, such as, permeability, porosity, or saturations, may correspond to a discrete value that is associated with a particular grid cell or coarse grid block. However, by using discrete values to represent a portion of a geological region, a discretization error may occur in a reservoir simulation. Thus, finer grids may reduce discretization errors as the numerical approximation of a finer grid is closer to the exact solution, however, through a greater computational cost. As shown in FIG. 2B, for example, the reservoir grid model 290 may include various fine-grid models (that is, fine-grid model A 251, fine-grid model B 252) that are surrounded by coarse block regions. Likewise, the original reservoir grid model without any coarsening may also be a fine-grid model.

In some embodiments, proxy models or reduced-order models may be generated for performing a reservoir simulation. For example, one way to reduce model dimensionality is to reduce the number of grid blocks or grid cells. By averaging reservoir properties into larger blocks while preserving the flow properties of a reservoir model, computational time of a reservoir simulation may be reduced. In general, coarsening may be applied to cells that do not contribute to a total flow within a reservoir region because a slight change on such reservoir properties may not affect the output of a simulation. Accordingly, different levels of coarsening may be used on different regions of the same reservoir model. As such, a coarsening ratio may correspond to a measure of coarsening efficiency, which may be defined as a total number of cells in a coarse reservoir model divided by the original number of cells in the original reservoir model.

Flow properties, such as flux, may be defined as a reservoir fluid (for example, oil or natural gas) that flows between any two grid blocks. Likewise, grid cells or blocks may be upscaled in a method that reduces the computational demand on running simulations using fewer grid cells. However, a grid model may lose accuracy in a reservoir simulation if the underlying properties differ too much from the original fine-grid model. Accordingly, one or more solutions as broadly contemplated are effective in providing accurate modelling in a context of utilizing coarse grid blocks while avoiding the computational cost often associated with the use of fine grid blocks.

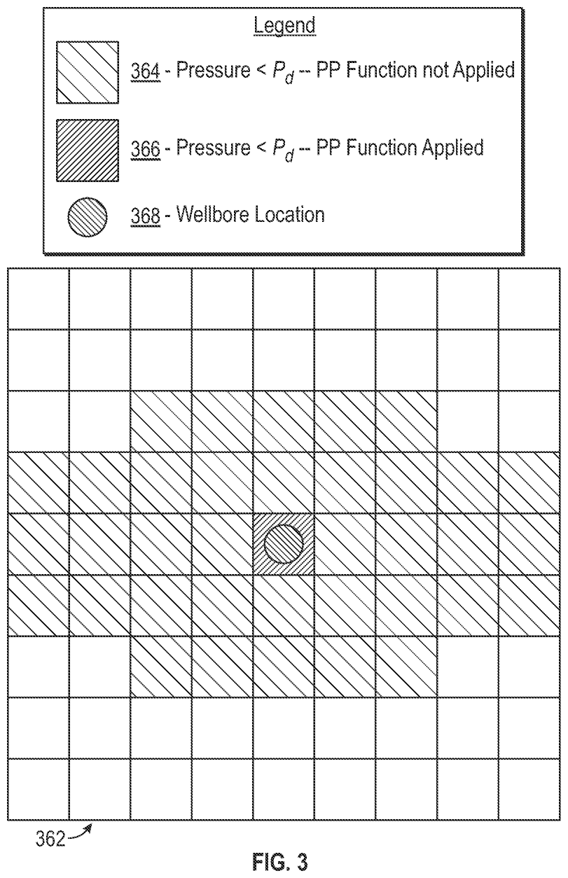

As such, the disclosure now turns to working examples of systems and methods of simulating flowrate in a reservoir model in accordance with one or more embodiments, as described and illustrated with respect to FIGS. 3-6. It should be understood and appreciated that these merely represent illustrative examples, and that a great variety of possible implementations are conceivable within the scope of embodiments as broadly contemplated.

Generally, the presence of liquid condensate in the pore system of rich gas reservoirs blocks the flow of gas in a manner to reduce gas permeability. Normally, this may be observed via pressure transient analysis (PTA), which involves analyzing well pressure data that has been obtained from well testing. The PTA may include the calculation of pressure derivatives (that is, a function of rate of change of pressure over time). However, as it is often cost-prohibitive to carry out such analysis, a “pseudo-pressure” (PP) modelling option may be pursued.

As is generally known, pseudo-pressure is a mathematical pressure function that accounts for the variable compressibility and viscosity of gas with respect to pressure. Indeed, the PP function is often used because the PP function is computationally less expensive. For instance, under a general assumption that the extent of significant condensate blockage is limited to areas close to the wellbore (for example, on the order of merely a few feet), a coarse model utilizing PP can replace what normally would be a model involving local grid refinement (at a fine scale) in the immediate region of the wellbore. Typically, the only related modification in the PP function is in simulating the wellbore area to account for further pressure drops at the wellbore location in light of the noted assumption.

However, in the case of rich gas condensate reservoirs, condensate blockage effects often occur up to several hundred feet away from the wellbore. As can be appreciated with reference to FIG. 2B and its related discussion, the distances may equate to several model cells in coarse modelling. The conventional PP function is comparatively less reliable at this distance if not otherwise modified.

In accordance with one or more embodiments, an improvement over conventional PP modelling in the context of rich gas condensate reservoirs, where condensate blockage can be modelled for locations up to a considerable (lateral) distance from the wellbore may be made. Particularly, fundamental flow modelling equations associated with the pseudo-pressures determined for grid cells corresponding to the wellbore location can be extended to all cells in a model where pressure is determined to be less than the dew point pressure (or dew pressure) P_{d}. Advantageously, this may avail the practical and cost-effective use of coarse grids in simulation along with considerable accuracy where the course grids are applicable on a larger scale, such as full field modelling.

In accordance with one or more embodiments, the following equation may be utilized for modelling inflow at the wellbore (for example, via a simulator such as that indicated at 160 in FIG. 1). The equation may be utilized when using the PP function (particularly, via applying a pseudo-pressure blocking factor β) and applying the PP function to solely the well cell location as noted. Thus, the equation relative to each layer l, is:

q_{c,l}=β×WIₗ×λ_{c,l}×(pᵢ−p_{w,l}) (Eq. 1)

where, q_{c,l} is flowrate (for a given layer l), WIₗ is the well index at the layer l, λ_{c,l} is a variable representing upstream hydrocarbon component molar mobility, pᵢ is the well grid cell pressure, and p_{w,l} is a term representing wellbore pressure taking into account gravity and friction effects for a given layer l.

In accordance with one or more embodiments, in a context of producing completions, the “mobility” variable from fundamental Equation 1 may be defined as provided for in Equation 2:

λ_{c,l}=((kᵣₒ×ρₒ/μₒ)ₗ×x_{c})+((k_{rg}×ρ_{g}/μ_{g})ₗ×y_{c}) (Eq. 2)

where in Equation 2 kᵣₚ represents relative permeability, ρₚ corresponds to molar density, and μₚ is viscosity, where subscript p conveys a hydrocarbon phase (that is, oil o or gas g). Also, in Equation (2), x_{c} and y_{c} represent oil and gas component-mole-fractions, respectively. Thus, the mobility variable for a given cell and layer (λ_{c,l}) is a function of simulated saturation and pressure in the cell (or grid block).

In accordance with one or more embodiments, may be determined in any suitable manner, of which an illustrative and non-restrictive example is as follows:

$$β = \frac{{\int }_{{p}_{w , l}}^{{p}_{i}} {λ}_{hc} dp}{{λ}_{hc @ {p}_{i}} \times ( {p}_{i} - {p}_{w , l} )} \qquad ( Eq . 3 )$$

As shown in Equation 3, in accordance with one or more embodiments, the pseudo-pressure blocking factor is a function of grid cell mobility relative to hydrocarbon phases existing at different pressures. Particularly, λ_{hc} represents grid cell mobility as a function of different hydrocarbon phases that exist when pressure is at a given value (from p_{w,l} to pᵢ with respect to the integral function in the numerator). At the same time, λ_{hc#p}_{ᵢ} represents grid cell mobility when pressure is at pᵢ.

In accordance with one or more embodiments, the use of Equations 1, 2 and 3 (in

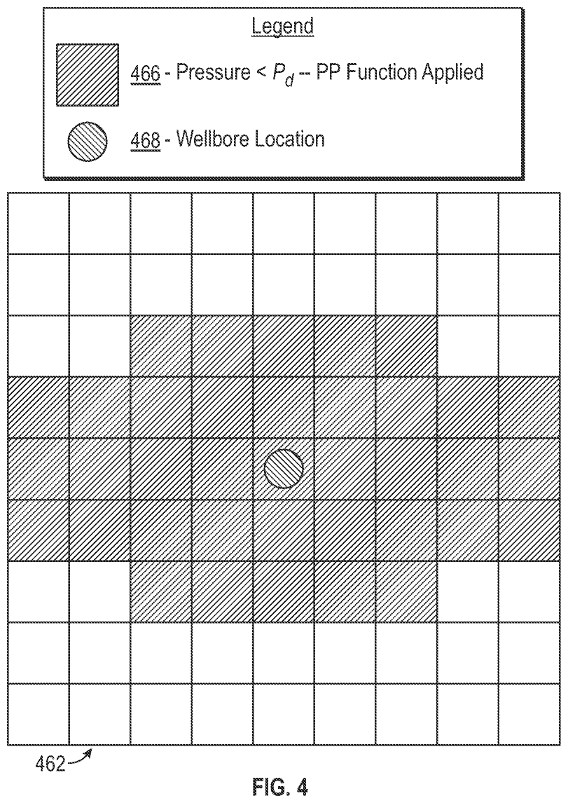

modelling via a PP function) is expanded to those cells in the model where the pressure is determined to be less than P_{d}. Thus, Equations 1, 2 and 3 are applied to grid cells away from the wellbore as well as at the wellbore itself, where pressure is determined to be less than P_{d}. The effect of this modification is illustrated in FIGS. 3 and 4.

As such, in accordance with one or more embodiments, FIGS. 3 and 4 each schematically illustrate one layer of a coarse grid model (362 and 462, respectively) for a condensate rich gas reservoir. In both figures, those cells where pressure is determined to be less than P_{d} are shaded (364) or hatched (366, 466). The wellbore location in both figures is indicated with a black dot (368, 468). Further, among the cells where pressure is determined to be less than P_{d}, the hatched cells (366, 466) are understood as being treated with the PP function, while the shaded cells (364) are not so treated. FIG. 3 represents a conventional coarse grid model 362, where a pseudo-pressure function is applied solely for the grid cell corresponding to the wellbore location 368. FIG. 4 schematically illustrates a coarse grid model 462, where a pseudo-pressure function is additionally applied to grid cells away from the wellbore location 468.

Thus, FIG. 3 illustrates that in a conventional coarse model employing a PP function, relative to a given layer, only the hatched cell (366) corresponding to the wellbore location (368) benefits from what is understood to be a more accurate flowrate calculation. However, for the numerous shaded cells (364) outside of the wellbore location (368), where pressure is likewise determined to be less than P_{d}, will not be similarly treated, constrained by the conventional assumption that the PP function need only be applied to the wellbore location (368) and by an assumption that a more accurate calculation of pressure losses away from the wellbore (364) is not warranted by additional computational expense. Thus, the calculated flowrates in these numerous shaded cells (364) are likely to be inaccurate. On the other hand, in accordance with one or more embodiments as shown in FIG. 4, all of the cells around the wellbore location (468) with pressure less than P_{d} are shown as hatched (466) to indicate that a flowrate calculation is applied there similarly to the wellbore location, leading to more accurate calculations overall. Here, the need to mitigate condensate banking problems by improving hydrocarbon recovery is more aptly recognized, and extending the aforementioned flowrate calculation to the hatched cells (466) results in greatly improved calculations to exponentially greater practical effect.

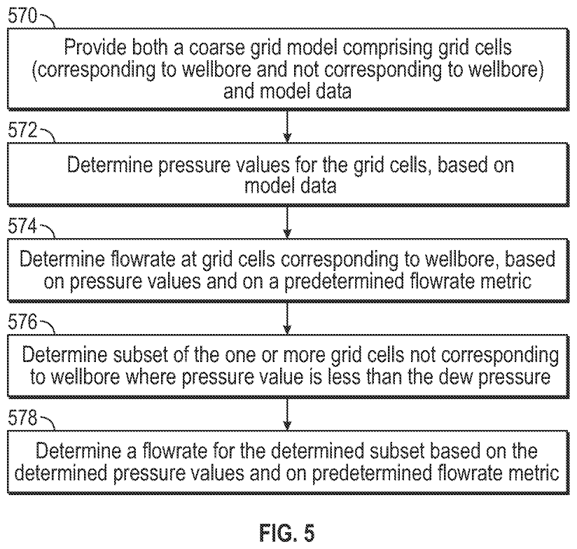

FIG. 5 shows a flowchart of a method that may be carried out in accordance with one or more embodiments.

As such, in accordance with one or more embodiments, a coarse grid model may be provided for use by a computer processor (570). The computer processor may correspond to that indicated at 891 in FIG. 6, and may for use with a reservoir simulator such as that indicated at 160 in FIGS. 1 and 6. The coarse grid model may include for its part a plurality of grid cells in a plurality of layers, including grid cells corresponding to a wellbore and grid cells not corresponding to the wellbore. Also provided for use by the computer processor are model data for a reservoir region of interest (that is, a reservoir region for which a modelling of flowrates is desired). By way of illustrative and non-restrictive example, the coarse grid model could be similar to either or both of the coarse grids 262 and 462 described and illustrated in FIGS. 2 and 4, respectively, and the model data could correspond to the reservoir data indicated at 898 in FIG. 6.

In accordance with one or more embodiments, using the computer processor, a plurality of pressure values may be determined for the grid cells corresponding to the wellbore and the grid cells not corresponding to the wellbore based on the model data (572).

Using the computer processor, a flowrate may be determined at the grid cells corresponding to the wellbore based on the determined pressure values and on a predetermined flowrate metric (574). The flowrate metric may be a function of well index, a pressure quantity, and a mobility variable. The mobility variable may be a non-linear function of gas condensate saturation and pressure. By way of illustrative and non-restrictive example, a related equation and variables may correspond to those shown and described with respect to Equations (1) and (2). A reservoir simulator such as that indicated at 160 in FIGS. 1 and 6 may be used for determining flowrate.

As such, in accordance with at least one embodiment, the flowrate metric may be a product of the well index (WIₗ), the pressure quantity (pᵢ−p_{w,l}), the mobility variable (λ_{c,l}) and the pseudo-pressure blocking factor (β). Further, the mobility variable may represent upstream hydrocarbon component molar mobility and may be a sum of an oil component ((kᵣₒ×ρₒ/μₒ)ₗ×x_{c}) and a gas component ((k_{rg}×ρ_{g}/μ_{g})ₗ×y_{c}). The oil component may be a product of an oil component mole fraction (x_{c}) and a relative permeability term ((kᵣₒ×ρₒ/μₒ)ₗ). The gas component may be a product of a gas component mole fraction (y_{c}) and a relative permeability term ((k_{rg}×ρ_{g}/μ_{g})ₗ).

In accordance with one or more embodiments, using the computer processor, a subset is determined of the one or more grid cells not corresponding to the wellbore, where a determined pressure value is less than the dew pressure (576). Additionally, using the computer processor, a flowrate is determined for the determined subset of the one or more grid cells based on the determined pressure values and on the predetermined flowrate metric (578). By way of illustrative and non-restrictive example, this is generally described and illustrated with respect to FIG. 4, while a reservoir simulator, such as that indicated at 160 in FIGS. 1 and 6, may be used for determining flowrate.

FIG. 6 schematically illustrates a computing device and related components, in

accordance with one or more embodiments. As such, FIG. 6 generally depicts a block diagram of a computer system 885 used to provide computational functionalities associated with described algorithms, methods, functions, processes, flows, and procedures as described in this disclosure, according to one or more embodiments. In this respect, computer 885 may interface with a reservoir simulator 160 such as that described and illustrated with respect to FIG. 1, either directly (for example, via hard-wired connection) or over an internal or external network 899. Alternatively, the computer 885 illustrated in FIG. 6 may correspond directly to, or house, the reservoir simulator described and illustrated with respect to FIG. 1.

In accordance with one or more embodiments, the illustrated computer 885 is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer 885 may include a computer that includes an input device, such as a keypad, keyboard, touch screen, or other device that can accept user information, and an output device that conveys information associated with the operation of the computer 885, including digital data, visual, or audio information (or a combination of information), or a GUI.

The computer 885 can serve in a role as a client, network component, a server, a database or other persistency, or any other component (or a combination of roles) of a computer system for performing the subject matter described in the instant disclosure. The illustrated computer 885 is communicably coupled with a network 899. In some implementations, one or more components of the computer 885 may be configured to operate within environments, including cloud-computing-based, local, global, or other environment (or a combination of environments).

At a high level, the computer 885 is an electronic computing device operable to receive, transmit, process, store, or manage data and information associated with the described subject matter. According to some implementations, the computer 885 may also include or be communicably coupled with an application server, e-mail server, web server, caching server, streaming data server, business intelligence (BI) server, or other server (or a combination of servers).

The computer 885 can receive requests over network 899 from a client application (for example, executing on another computer 885) and responding to the received requests by processing the said requests in an appropriate software application. In addition, requests may also be sent to the computer 885 from internal users (for example, from a command console or by other appropriate access method), external or third-parties, other automated applications, as well as any other appropriate entities, individuals, systems, or computers.

Each of the components of the computer 885 can communicate using a system bus 887. In some implementations, any or all of the components of the computer 885, both hardware or software (or a combination of hardware and software), may interface with each other or the interface 889 (or a combination of both) over the system bus 887 using an application programming interface (API) 895 or a service layer 897 (or a combination of the API 895 and service layer 897. The API 895 may include specifications for routines, data structures, and object classes. The API 895 may be either computer-language independent or dependent and refer to a complete interface, a single function, or even a set of APIs. The service layer 897 provides software services to the computer 885 or other components (whether or not illustrated) that are communicably coupled to the computer 885. The functionality of the computer 885 may be accessible for all service consumers using this service layer. Software services, such as those provided by the service layer 897, provide reusable, defined business functionalities through a defined interface. For example, the interface may be software written in JAVA, C++, or other suitable language providing data in extensible markup language (XML) format or another suitable format. While illustrated as an integrated component of the computer 885, alternative implementations may illustrate the API 895 or the service layer 897 as stand-alone components in relation to other components of the computer 885 or other components (whether or not illustrated) that are communicably coupled to the computer 885. Moreover, any or all parts of the API 895 or the service layer 897 may be implemented as child or sub-modules of another software module, enterprise application, or hardware module without departing from the scope of this disclosure.

The computer 885 includes an interface 889. Although illustrated as a single interface 889 in FIG. 6, two or more interfaces 889 may be used according to particular needs, desires, or particular implementations of the computer 885. The interface 889 is used by the computer 885 for communicating with other systems in a distributed environment that are connected to the network 899. Generally, the interface 889 includes logic encoded in software or hardware (or a combination of software and hardware) and operable to communicate with the network 899. More specifically, the interface 889 may include software supporting one or more communication protocols associated with communications such that the network 899 or interface's hardware is operable to communicate physical signals within and outside of the illustrated computer 885.

The computer 885 includes at least one computer processor 891. Although illustrated as a single computer processor 891 in FIG. 6, two or more processors may be used according to particular needs, desires, or particular implementations of the computer 885. Generally, the computer processor 891 executes instructions and manipulates data to perform the operations of the computer 885 and any algorithms, methods, functions, processes, flows, and procedures as described in the instant disclosure.

The computer 885 also includes a memory 892 that holds data for the computer 885 or other components (or a combination of both) that can be connected to the network 899. For example, memory 892 can be a database storing data consistent with this disclosure. Although illustrated as a single memory 892 in FIG. 6, two or more memories may be used according to particular needs, desires, or particular implementations of the computer 885 and the described functionality. While memory 892 is illustrated as an integral component of the computer 885, in alternative implementations, memory 892 can be external to the computer 885.

The application 893 is an algorithmic software engine providing functionality according to particular needs, desires, or particular implementations of the computer 885, particularly with respect to functionality described in this disclosure. For example, application 893 can serve as one or more components, modules, and applications. Further, although illustrated as a single application 893, the application 893 may be implemented as multiple applications 893 on the computer 885. In addition, although illustrated as integral to the computer 885, in alternative implementations, the application 893 can be external to the computer 885.

In one or more embodiments, the reservoir simulator 160 may be an application that is operated on the computer 885 when utilized; thus, in FIG. 6, reservoir simulator 160 is depicted as coincident with application 893. When utilized, data for the reservoir (898) is loaded from memory 892 and utilized by the reservoir simulator 160. In one or more embodiments, the reservoir simulator 160 may be an application 893 residing in, or in memory 892 on the computer 885. In one or more embodiments, the reservoir simulator 160 may reside on the network 899. In such an instance, reservoir data 898 is acquired by the reservoir simulator 160 and may be processed through the computer processor 891, processors in communication with the network 899, or both. In this connection, both the reservoir simulator 160 and reservoir 868 may be accessed and run on a remote server, with results displayed locally on computer 885.

There may be any number of computers 885 associated with, or external to, a computer system containing computer 885, wherein each computer 885 communicates over network 899. Further, the term “client,” “user,” and other appropriate terminology may be used interchangeably as appropriate without departing from the scope of this disclosure. Moreover, this disclosure contemplates that many users may use one computer 885, or that one user may use multiple computers 885.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, any means-plus-function clauses are intended to cover the structures described herein as performing the recited function(s) and equivalents of those structures. Similarly, any step-plus-function clauses in the claims are intended to cover the acts described here as performing the recited function(s) and equivalents of those acts. It is the express intention of the applicant not to invoke 35 U.S.C. § 112(f) for any limitations of any of the claims herein, except for those in which the claim expressly uses the words “means for” or “step for” together with an associated function.

What is claimed:

1. A method, comprising:
providing, using a computer processor, a coarse grid model comprising a plurality of grid cells in a plurality of layers, including grid cells corresponding to a wellbore and grid cells not corresponding to the wellbore;
providing, using the computer processor, model data for a reservoir region of interest;
determining, using the computer processor, a plurality of pressure values for the grid cells corresponding to the wellbore and for the grid cells not corresponding to the wellbore, based on the model data for the reservoir region of interest;
determining, using the computer processor, a flowrate at the grid cells corresponding to the wellbore based on the determined pressure values and on a predetermined flowrate metric,
where the flowrate metric is a function of well index, a pressure quantity, and a mobility variable, and
where the mobility variable is a non-linear function of gas condensate saturation and pressure;
determining, using the computer processor, a subset of the grid cells not corresponding to the wellbore where a determined pressure value is less than dew pressure; and
determining, using the computer processor, a flowrate for the determined subset of the one or more grid cells based on the determined pressure values and on the predetermined flowrate metric.

2. The method according to claim 1, wherein the flowrate metric is a product of the well index, the pressure quantity, the mobility variable and a pseudo-pressure blocking factor.

3. The method according to claim 2, wherein the pseudo-pressure blocking factor is a function of grid cell mobility relative to hydrocarbon phases existing at different pressures.

4. The method according to claim 1, wherein the mobility variable represents upstream hydrocarbon component molar mobility.

5. The method according to claim 1, wherein the mobility variable is a sum of an oil component and a gas component.

6. The method according to claim 5, wherein the oil component is a product of an oil component mole fraction and a relative permeability term.

7. The method according to claim 5, wherein the gas component is a product of a gas component mole fraction and a relative permeability term.

8. The method according to claim 1, wherein the well is a gas condensate well.

9. A system, comprising:
a reservoir simulator comprising a computer processor, wherein the reservoir simulator comprises functionality for:
providing a coarse grid model comprising a plurality of grid cells in a plurality of layers, including grid cells corresponding to a wellbore and grid cells not corresponding to the wellbore;
providing model data for a reservoir region of interest;
determining a plurality of pressure values for the grid cells corresponding to the wellbore and for the grid cells not corresponding to the wellbore, based on the model data for the reservoir region of interest;
determining a flowrate at the grid cells corresponding to the wellbore based on the determined pressure values and on a predetermined flowrate metric,
where the flowrate metric is a function of well index, a pressure quantity, and a mobility variable, and
where the mobility variable is a non-linear function of gas condensate saturation and pressure;
determining a subset of the grid cells not corresponding to the wellbore where a determined pressure value is less than dew pressure; and
determining a flowrate for the determined subset of the one or more grid cells based on the determined pressure values and on the predetermined flowrate metric.

10. The system according to claim 9, wherein the flowrate metric is a product of the well index, the pressure quantity, the mobility variable and a pseudo-pressure blocking factor.

11. The system according to claim 9, wherein the pseudo-pressure blocking factor is a function of grid cell mobility relative to hydrocarbon phases existing at different pressures.

12. The system according to claim 9, wherein the mobility variable represents upstream hydrocarbon component molar mobility.

13. The system according to claim 9, wherein the mobility variable is a sum of an oil component and a gas component.

14. The system according to claim 13, wherein the oil component is a product of an oil component mole fraction and a relative permeability term.

15. The system according to claim 14, wherein the gas component is a product of a gas component mole fraction and a relative permeability term.

16. The system according to claim 9, wherein the well is a gas condensate well.

17. A non-transitory computer readable medium storing instructions executable by a computer processor, the instructions comprising functionality for:
providing a coarse grid model comprising a plurality of grid cells in a plurality of layers, including grid cells corresponding to a wellbore and grid cells not corresponding to the wellbore;
providing model data for a reservoir region of interest;
determining a plurality of pressure values for the grid cells corresponding to the wellbore and for the grid cells not corresponding to the wellbore, based on the model data for the reservoir region of interest;
determining a flowrate at the grid cells corresponding to the wellbore based on the determined pressure values and on a predetermined flowrate metric,
where the flowrate metric is a function of well index, a pressure quantity, and a mobility variable, and
where the mobility variable is a non-linear function of gas condensate saturation and pressure;
determining a subset of the grid cells not corresponding to the wellbore where a determined pressure value is less than dew pressure; and
determining a flowrate for the determined subset of the one or more grid cells based on the determined pressure values and on the predetermined flowrate metric.

18. The non-transitory computer readable medium according to claim 17, wherein the flowrate metric is a product of the well index, the pressure quantity, the mobility variable and a pseudo-pressure blocking factor.

19. The non-transitory computer readable medium according to claim 17, wherein the mobility variable represents upstream hydrocarbon component molar mobility.

20. The non-transitory computer readable medium according to claim 17, wherein the mobility variable is a sum of an oil component and a gas component.
